(19) United States
(12) Patent Application Publication
(10) Pub. No.: US 2015/0145020 A1
(43) Pub. Date: May 28, 2015

(54) SEMICONDUCTOR DEVICE AND METHOD OF FABRICATING THE SAME

(71) Applicants: CHAEHO KIM, Gyeonggi-do (KR); KIHYUN HWANG, Gyeonggi-do (KR); DONGWOO KIM, Incheon (KR); WOONG LEE, Seoul (KR); JUNGGEUN JEE, Seoul (KR)

(72) Inventors: CHAEHO KIM, Gyeonggi-do (KR); KIHYUN HWANG, Gyeonggi-do (KR); DONGWOO KIM, Incheon (KR); WOONG LEE, Seoul (KR); JUNGGEUN JEE, Seoul (KR)

(21) Appl. No.: 14/510,532

(22) Filed: Oct. 9, 2014

(30) Foreign Application Priority Data
Nov. 27, 2013 (KR) 10-2013-0145469

(51) Int. Cl. H01L 27/115; H01L 29/66; H01L 21/02

(52) U.S. Cl. CPC H01L 27/11582; H01L 21/02488; H01L 21/02491; H01L 21/02507; H01L 21/02587; H01L 29/66666; H01L 29/66833
USPC 257/324; 438/269

(57) ABSTRACT

A method of fabricating a three-dimensional (3D) semiconductor memory device is provided. Sacrificial layers and insulating layers are alternately and repeatedly stacked on a top surface of a substrate to form a thin layer structure. A channel structure penetrating the thin layer structure is formed to be in contact with the substrate. A trench penetrating the thin layer structure is formed. The sacrificial layers, the insulating layers and the substrate are exposed in the trench. A recess region formed in the substrate exposed by the trench. A semiconductor pattern filling is formed the recess region. The sacrificial layers exposed by the trench are replaced with gate patterns.

### CROSS-REFERENCE TO RELATED APPLICATION

This application claims priority under 35 U.S.C. §119 to Korean Patent Application No. 10-2013-0145469, filed on Nov. 27, 2013, in the Korean Intellectual Property Office, the disclosure of which is incorporated by reference herein in its entirety.

### TECHNICAL FIELD

The inventive concept relates to a semiconductor device and a method of fabricating the same.

### DISCUSSION OF RELATED ART

Three-dimensional (3D) semiconductor devices including memory cells vertically stacked have been developed to increase memory storage. For example, to increase the integration density of the semiconductor devices, memory cells are stacked on each other in a vertical direction. However, when memory cells are stacked in a vertical direction, it may be difficult to provide uniform operating characteristics.

### SUMMARY

According to an exemplary embodiment of the present inventive concept, a method of fabricating a three-dimensional (3D) semiconductor memory device is provided. Sacrificial layers and insulating layers are alternately and repeatedly stacked on a top surface of a substrate to form a thin layer structure. A channel structure penetrating the thin layer structure is formed to be in contact with the substrate. A trench penetrating the thin layer structure is formed. The sacrificial layers, the insulating layers and the substrate are exposed in the trench. A recess region formed in the substrate exposed by the trench. A semiconductor pattern filling is formed the recess region. The sacrificial layers exposed by the trench are replaced with gate patterns.

According to an exemplary embodiment of the present embodiment, a three-dimensional (3D) semiconductor memory device includes a stack structure, a channel structure, a semiconductor pattern, and a device isolation pattern. The stack structure includes gate patterns and insulating patterns alternately stacked on a top surface of a substrate. The substrate includes a recess region of which a bottom surface is lower than the top surface. A channel structure is disposed on a first sidewall of the stack structure and connected to the substrate. A semiconductor pattern is disposed in the recess region. A device isolation pattern is disposed on a top surface of the semiconductor pattern and a second sidewall of the stack structure. The first sidewall is opposite to the second sidewall.

According to an exemplary embodiment of the present embodiment, a three-dimensional (3D) semiconductor memory device includes a substrate, a semiconductor pattern, a device isolation, a first stack structure, and a second stack structure. The substrate includes a recess region including a sloped sidewall and a bottom surface. The bottom surface of the recess region is lower than a top surface of the substrate. The semiconductor pattern is disposed in the recess region. The device isolation pattern is disposed on the semiconductor pattern. The first stack structure is disposed on a first sidewall of the device isolation pattern. The second stack structure is disposed on a second sidewall of the device isolation pattern. The first and second stack structures including gate patterns and insulating patterns alternately stacked on the top surface of the substrate.

### BRIEF DESCRIPTION OF THE DRAWINGS

These and other features of the inventive concept will become more apparent by describing hi detail exemplary embodiments thereof with reference to the accompanying drawings of which:

FIG. 1 is a schematic circuit diagram illustrating a three-dimensional (3D) semiconductor memory device according to an exemplary embodiment of the inventive concept;

FIG. 2 is a plan view illustrating a 3D semiconductor memory device according to an exemplary embodiment of the inventive concept;

FIG. 3 is a cross-sectional view, taken along line I-I′ of FIG. 2, illustrating a 3D semiconductor memory device according to an exemplary embodiment of the inventive concept;

FIG. 4 is an enlarged view of a portion ‘A’ of FIG. 3;

FIG. 5 is an enlarged view of a portion ‘A’ of FIG. 3 to illustrate a modified embodiment of a 3D semiconductor memory device according to an exemplary embodiment of the inventive concept;

FIGS. 6 to 8 are enlarged views of a portion ‘B’ of FIG. 3;

FIGS. 9 to 18 are cross-sectional views taken along line I-I′ of FIG. 2 to illustrate a method of fabricating a 3D semiconductor memory device according to an exemplary embodiment of the inventive concept;

FIG. 19 is an enlarged view corresponding to a portion ‘C’ of FIG. 18 of a comparison example not including a third semiconductor pattern of FIG. 18;

FIG. 20 is a cross-sectional view taken along line I-I′ of FIG. 2 to illustrate a 3D semiconductor memory device according to an exemplary embodiment of the inventive concept;

FIGS. 21 to 23 are cross-sectional views taken along line I-I′ of FIG. 2 to illustrate a method of fabricating a 3D semiconductor memory device according to an exemplary embodiment of the inventive concept;

FIG. 24 is a schematic block diagram illustrating a memory system including a 3D semiconductor memory device according to an exemplary embodiment of the inventive concept;

FIG. 25 is a schematic block diagram illustrating a memory card including a 3D semiconductor memory device according to an exemplary embodiment of the inventive concept; and

FIG. 26 is a schematic block diagram illustrating an information processing systems including a 3D semiconductor memory device according to an exemplary embodiment of the inventive concept.

### DETAILED DESCRIPTION OF EXEMPLARY EMBODIMENTS

Exemplary embodiments of the inventive concept will be described below in detail with reference to the accompanying drawings. However, the inventive concept may he embodied in different forms and should not be construed as limited to the embodiments set forth herein. In the drawings, the thickness of layers and regions may be exaggerated for clarity. It will also be understood that when an element is referred to as being “on” another element or substrate, it may be directly on the other element or substrate, or intervening layers may also be present. It will also be understood that when an element is referred to as being “coupled to” or “connected to” another element, it may he directly coupled to or connected to the other element, or intervening elements may also be present. Like reference numerals may refer to the like elements throughout the specification and drawings.

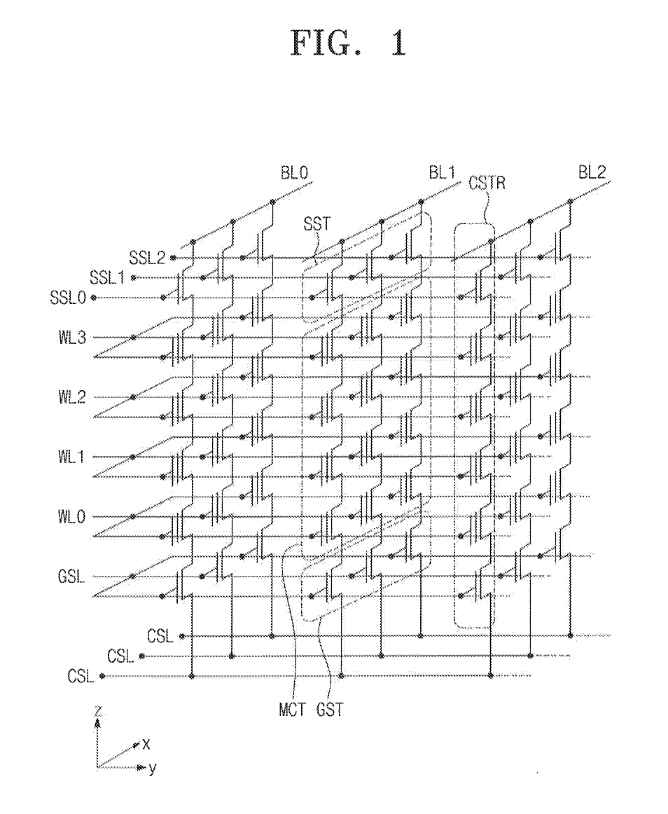

FIG. 1 is a schematic circuit diagram illustrating a three-dimensional (3D) semiconductor memory device according to an exemplary embodiment of the inventive concept.

Referring to FIG. 1, a cell array of a 3D semiconductor memory device according to an exemplary embodiment includes a common source line CSL, bit lines BL, and cell strings CSTR disposed between the common source lines CSL and the bit lines BL.

The bit lines BL are two-dimensionally arranged, and the cell strings CSTR are connected in parallel to each of the bit lines BL. The cell strings CSTR are connected in common to the common source lines CSL. For example, the cell strings CSTR are disposed between the common source lines CSL and the plurality of bit lines BL. The common source lines CSL may be provided in plural. In this case, the common source lines CSL may be two-dimensionally arranged. The same voltage may be applied to the common source lines CSL. Alternatively, the common source lines CSL may be electrically controlled independently of each other.

Each of the cell strings CSTR includes a ground selection transistor GST connected to the common source line CSL, a string selection transistor SST connected to the bit line BL, and memory cell transistors MCT disposed between the ground and string selection transistors GST and SST. The ground selection transistor GST, the memory cell transistors MCT, and the string selection transistor SST may be connected in series to each other.

The common source lines CSL are connected in common to sources of the ground selection transistors GST. Ground selection lines GSL, word lines WL0 to WL3 and string selection lines SSL, which are disposed between the common source lines CSL and the bit lines BL, may serve as gate electrodes of the ground selection transistors GST, the memory cell transistors MCT and the string selection transistors SST, respectively. Each of the memory cell transistors MCT may include a data storage element.

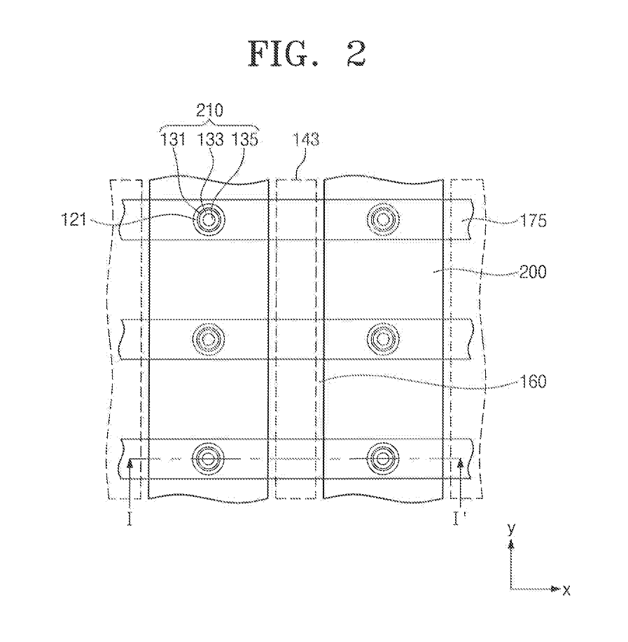

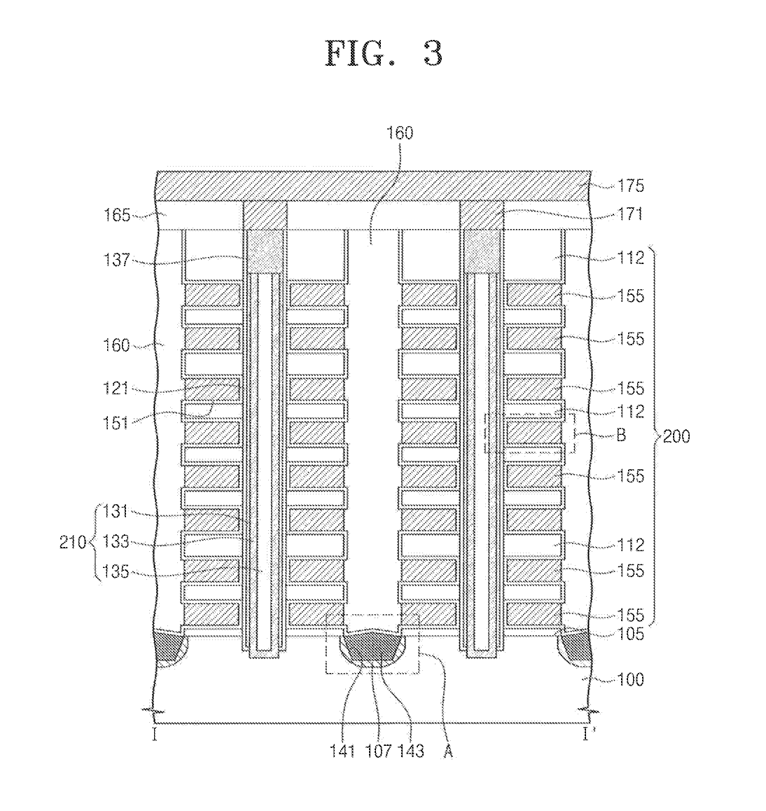

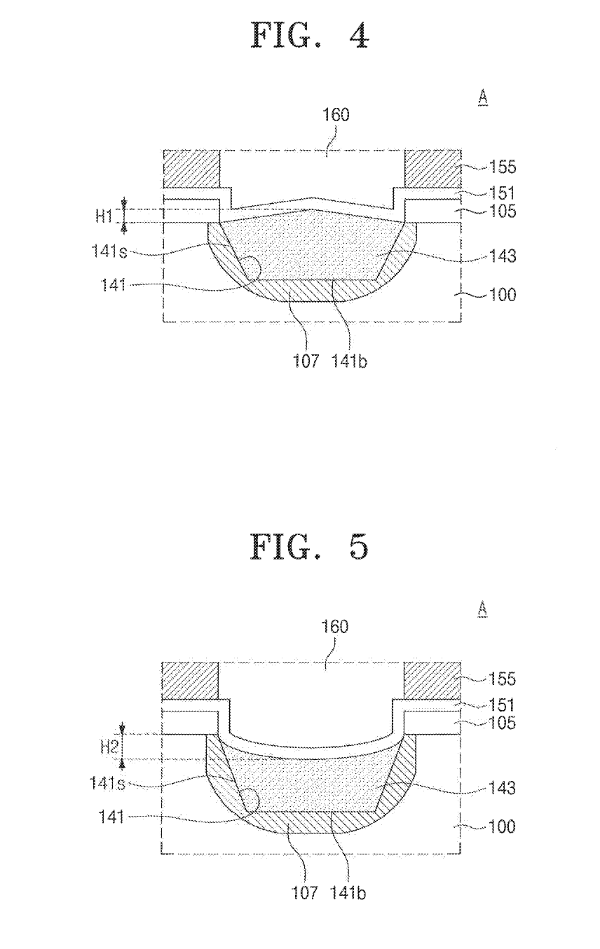

FIG. 2 is a plan view illustrating a 3D semiconductor memory device according to an exemplary embodiment of the inventive concept. FIG. 3 is a cross-sectional view, taken along line I-I′ of FIG. 2, illustrating a 3D semiconductor memory device according to an exemplary embodiment of the inventive concept. FIG. 4 is an enlarged view of a portion ‘A’ of FIG. 3, FIG. 5 is an enlarged view of a portion ‘A’ of FIG. 3 to illustrate a modified embodiment of a 3D semiconductor memory device according to an exemplary embodiment of the inventive concept.

Referring to FIGS. 2 and 3, stack structures 200 are disposed on a substrate 100. The stack structures 200 includes insulating patterns 112 and gate patterns 155 alternately and repeatedly stacked on the substrate 100.

The substrate 100 may be formed of a semiconductor material, For example, the substrate 100 may be a silicon substrate, a germanium substrate, or a silicon-germanium substrate. The substrate 100 may have a first conductivity type. A lower insulating layer 105 is disposed between the substrate 100 and the stack structures 200. The lower insulating layer 105 may be a silicon oxide layer formed by a thermal oxidation process. Alternatively, the lower insulating layer 105 may be a silicon oxide layer formed using a deposition technique. The lower insulating layer 105 may be thinner than the insulating patterns 112 disposed thereon. For example, a thickness of the lower insulating layer 105 may be in a range of about 200 Å to about. 300 Å.

The stack structures 200 are linear-shaped extending in one direction (e.g., a y-direction), as illustrated in FIG. 2. According to an exemplary embodiment, thicknesses of the insulating patterns 312 may be smaller than thicknesses of the gate patterns 155. Alternatively, thicknesses of some of the insulating patterns 112 may be greater than the thicknesses of the gate patterns 155. Alternatively, the thicknesses of the insulating patterns 112 may be substantially equal to the thicknesses of the gate patterns 155.

The uppermost gate patterns and lowermost gate patterns of the gate patterns 155 may serve as the gate electrodes of the ground and string selection transistors GST and SST as described with reference to FIG. 1. For example, the uppermost gate patterns may serve as the gate electrodes of the string selection transistors SST controlling electrical connections between bit lines 175 and channel structures 210, and the lowermost gate patterns may serve as the gate electrodes of the ground selection transistors GST controlling electrical connections between dopant regions 107 formed in the substrate 100 and the channel structures 210. The dopant regions 107 may correspond to the common source lines CSL of FIG. 1.

Channel structures 210 penetrate the stack structure 200. For example, the channel structures 210 disposed in each stack structure 200 are arranged in a straight line along the y-direction, as illustrated in FIG. 2. The inventive concept is not limited thereto, and the channel structures 210 may be arranged in a zigzag form along the y-direction.

The channel structures 210 penetrate the stack structures 200 to be electrically connected to the substrate 100. The channel structures 210 penetrate gate patterns 155 stacked on the substrate 100. The channel structures 210 may include a semiconductor material. Conductive pads 137 may be disposed on top ends of the channel structures 210. The conductive pads 137 may be doped with dopants. Alternatively, the conductive pads 137 may be formed of a conductive material. Bottom end portions of the channel structures 210 are inserted into the substrate 100, and thus bottom surfaces of the channel structure 210 are lower than a top surface of the substrate 100.

For example, the channel structures 210 include a first semiconductor pattern 131, a second semiconductor pattern 133, and a filling insulation pattern 135. The first semiconductor pattern 131 covers an inner sidewall of the stack structure 200. The first semiconductor pattern 131 may be pipe-shaped or macaroni-shaped. For example, the top and bottom ends of the first semiconductor pattern 131 are open. The first semiconductor pattern 131 is spaced apart from the substrate 100 and thus the first semiconductor pattern 131 is not in contact with the substrate 100. The second semiconductor pattern 133 may be pipe-shaped or macaroni-shaped having a closed bottom end. The inside of the second semiconductor pattern 133 is filled with the filling insulation pattern 135. The second semiconductor pattern 133 is in contact with an inner sidewall of the first semiconductor pattern 131 and the substrate 100 such that the second semiconductor pattern 133 may electrically connect the first semiconductor pattern 131 and the substrate 100.

The first and second semiconductor patterns 131 and 133 may include a semiconductor material. For example, the first and second semiconductor patterns 131 and 133 may include silicon (Si), germanium (Ge), or silicon-germanium (SiGe). The first and second semiconductor patterns 131 and 133 may be undoped with dopants. Alternatively, the first and second semiconductor patterns 131 and 133 may be doped with dopants of the first conductivity type which is the same as the conductivity type of the substrate 100. The first and second semiconductor patterns 131 and 133 may be in a poly-crystalline state or a single-crystalline state.

Vertical insulating patterns 12.1 are disposed between the stack structures 200 and the channel structures 210. The vertical insulating patterns 121 may be pipe-shaped or macaroni-shaped. The top and bottom ends of the vertical insulating patterns are open. The vertical insulating patterns 121 include bottom portions disposed between bottom surfaces of the first semiconductor patterns 131 and the substrate 100, and thus the first semiconductor patterns 131 are spaced apart from the substrate 100 without being in contact with the substrate 100.

The vertical insulating patterns 121 may include a data storage layer. The data storage layer may include a charge storage layer for storing data in a flash memory device. For example, the charge storage layer may include a trap insulating layer or an insulating layer including conductive nano-dots. Data stored in the data storage layer may be changed using the Fowler-Nordheim tunneling phenomenon caused by a voltage difference between the channel structure 210 and the gate pattern 155. Alternatively, the data storage layer may be a thin layer capable of storing data using an operating principle other than the Fowler-Nordheim tunneling phenomenon. For example, the data storage layer may be a thin layer for a phase change memory cell or a thin layer for a variable resistance memory cell.

Horizontal insulating patterns 151 are continuously disposed in sinuous manner between device isolation patterns 160 and the channel structures 210. For example, the horizontal insulating patterns 151 may be disposed between the gate patterns 155 and the vertical insulating pattern 121, between the gate patterns 155 and the insulating patterns 112, and between the insulating patterns 112 and the device isolation patterns 160. The horizontal insulating patterns 151 may be formed of at least one thin layer. The horizontal insulating patterns 151 may include a blocking insulating layer of a charge trap-type flash memory transistor,

The bit lines 175 cross over the stack structures 200. The bit lines 175 may be electrically connected to the conductive pads 137 through contact plugs 171.

Device isolation patterns 160 are disposed between the stack structures 200 adjacent to each other. The device isolation patterns 160 may include at least one of a silicon oxide layer, a silicon nitride layer, and a silicon oxynitride layer. Third semiconductor patterns 143 are disposed in recess regions 141 formed in the substrate 100. The recess regions 141 are disposed under the device isolation patterns 160. As illustrated in FIG. 2, the third semiconductor patterns 143 are linear-shaped extending in the y-direction.

Referring to FIG. 4, the recess regions 141 are defined by inclined surfaces 141s sloping downward from the top surface of the substrate 100 and a bottom surface 141b disposed between the inclined surfaces 141s. For example, a width of an upper region of the recess region 141 is greater than a width of a lower region of the recess region 141. Top surfaces of the third semiconductor patterns 143 are convex. For example, the third semiconductor patterns 143 completely fill the recess regions 141 and protrude outward from the recess regions 141. The convex top surfaces are higher than the top surface of the substrate 100. The topmost end of the convex top surface in the third semiconductor pattern 143 is lower than a bottom surface of the lowermost gate pattern 155. A height H1 between the top surface of the substrate 100 and the topmost end of the top surface of the third semiconductor pattern 143 may be about 200 Å or less. The inventive concept is not limited thereto, and the height H1 may be varied according to the characteristics of a fabricating process.

Referring to FIG. 5, the third semiconductor patterns 143 partially fill the recess regions 141 and may have a concave top surface lower than the top surface of the substrate 100. The concave top surface is curved inward in the recess region 141 and the recess region 141 is not completely filled with the third semiconductor pattern 143. A height H2 between a bottommost portion of the concave top surface and the top surface of the substrate 100 may be about 100 Å or less. The inventive concept is not limited thereto, and the height H2 may he varied according to the characteristics of a fabricating process.

The third semiconductor pattern 143 may include a semiconductor material including silicon, germanium, or silicon-germanium. However, the inventive concept is not limited thereto. For example, the third semiconductor pattern 143 may include at least one of a carbon nano structure, an organic semiconductor material, and a compound semiconductor material. For example, the third semiconductor pattern 143 may be an epitaxial pattern formed using a laser crystallization technique or an epitaxial growth technique where the substrate 100 including a semiconductor material may be used as a seed layer for epitaxial growth. In this case, the third semiconductor pattern 143 may have a single-crystalline structure, or a poly-crystalline structure having a grain size greater than that of a semiconductor material formed by a chemical vapor deposition (CVD) technique. The third semiconductor pattern 143 may be doped with dopants of a second conductivity type opposite to the first conductivity type of the substrate 100.

The common source regions 107 includes the third semiconductor pattern 143 and a portion of substrate 100 adjacent to the third semiconductor pattern 143. The common source region 107 may be doped with dopants of the second conductivity type. The common source region 107 may be line-shaped extending in the y-direction.

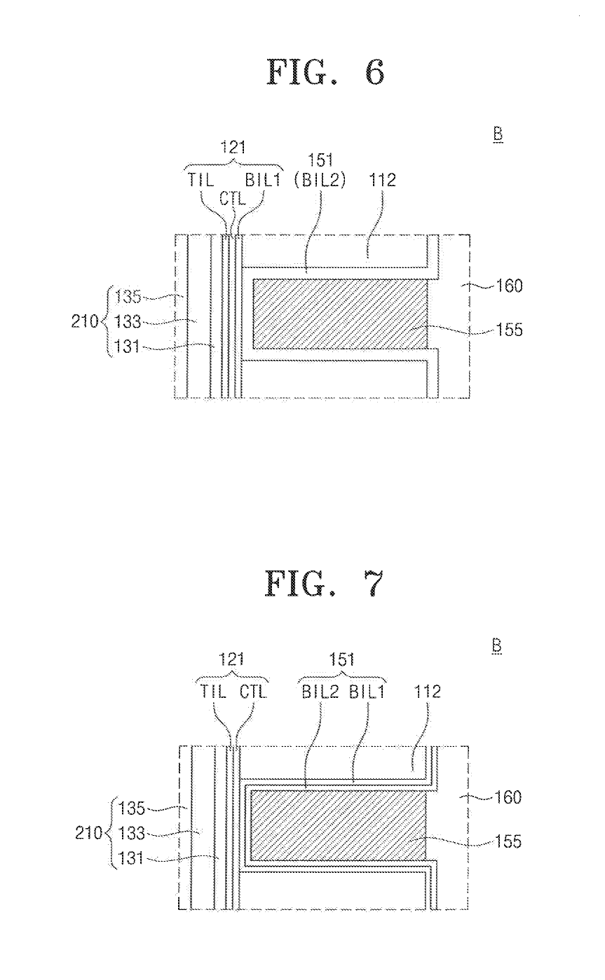

Hereinafter, structures of the vertical insulating pattern and the horizontal insulating pattern according to an exemplary embodiment will be described with reference to FIGS. 6 to 8. FIGS. 6 to 8 are enlarged views of a portion ‘B’ of FIG. 3.

Referring to FIG. 6, a vertical insulating pattern 121 includes a tunnel insulating layer TIL, a charge storage layer CTL, and a first blocking insulating layer BIL1. The tunnel insulating layer TIL is in contact with one sidewall of the channel structure 210, extending along the channel structure 210. The charge storage layer CTL is disposed between the tunnel insulating layer TIL and the first blocking insulating layer BIL1. A horizontal insulating pattern 151 includes a second blocking insulating layer BIL2. The second blocking insulating layer BIL2 is disposed between the first blocking insulating layer BIL1 and the gate pattern 155, extending onto the top surface and the bottom surface of the gate pattern 155,

Referring to FIG. 7 a vertical insulating pattern 121 may have a different structure from that of FIG. 6. The vertical insulating pattern 121 includes a tunnel insulating layer TIL and a charge storage layer CTL. A horizontal insulating pattern 151 includes first and second blocking insulating layers BIL1 and BIL2. The second blocking insulating layer BIL2 covers the top surface and the bottom surface of the gate pattern 155, extending onto one sidewall of the gate pattern 155. The first blocking insulating layer BIL1 is conformally formed on the second blocking insulating layer BIL2.

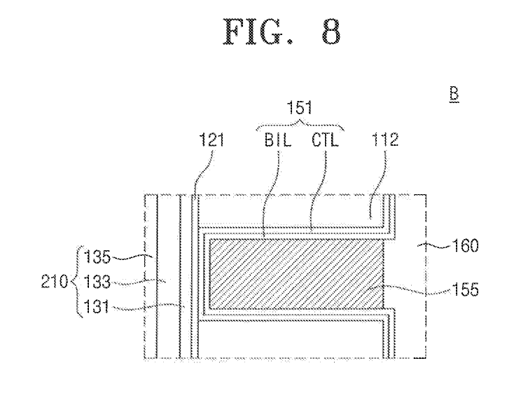

Referring to FIG. 8, a vertical insulating pattern 121 may have a different structure from those described above. The vertical insulating pattern 121 includes a tunnel insulating layer. A horizontal insulating pattern 151 includes a charge storage layer CTL and a blocking insulating layer BIL. The blocking insulating layer BIL covers the top surface and the bottom surface of the gate pattern 155, extending onto one sidewall of the gate pattern 155. The charge storage layer CTL is conformally formed on the blocking insulating layer BIL.

The charge storage layer CTL as described with reference to FIGS. 6 to 8 may include a trap insulating layer or an insulating layer including conductive nano dots. For example, the charge storage layer CTL may include at least one of, for example, a silicon nitride layer, a silicon oxynitride layer, a silicon-rich nitride layer, a nano-crystalline silicon layer, and a laminated trap layer.

The tunnel insulating layer TIL may include at least one of materials having an energy band gap greater than that of the charge storage layer CTL. For example, the tunnel insulating layer TIL may include a silicon oxide layer.

The blocking insulating layer BIL may include at least one of materials having an energy band gap smaller than that of the tunnel insulating layer TIL and greater than that of the charge storage layer CTL. For example, the blocking insulating layer BIL, may include a high-k dielectric layer such as an aluminum oxide layer and a hafnium oxide layer. The dielectric constant of at least a portion in the blocking insulating layer BIL may he greater than that of the tunnel insulating layer TIL.

The first and second blocking insulating layers BIL1 and BIL2 may be formed of different materials from each other. One of the first and second blocking insulating layers BIL1 and BIL2 may be formed of a material having an energy band gap smaller than that of the tunnel insulating layer TIL and greater than that of the charge storage layer CTL, and the other of the first and second blocking insulating layers BIL1 and BIL2 may be formed of a material having a dielectric constant smaller than that of the one blocking insulating layer. For example, the one of the first and second blocking insulating layers BIL1 and BIL2 may include at least one of the high-k dielectric layers such as the aluminum oxide layer and the hafnium oxide layer, and the other blocking insulating layer may include a silicon oxide layer. In this case, an effective dielectric constant of the first and second blocking insulating layers BIL1 and BIL2 may he greater than that of the tunnel insulating layer TIL.

The vertical insulating pattern 121 may he omitted, and the horizontal insulating pattern 151 may include the tunnel insulating layer TIL, the charge storage layer CTL, and the blocking insulating layer BIL.

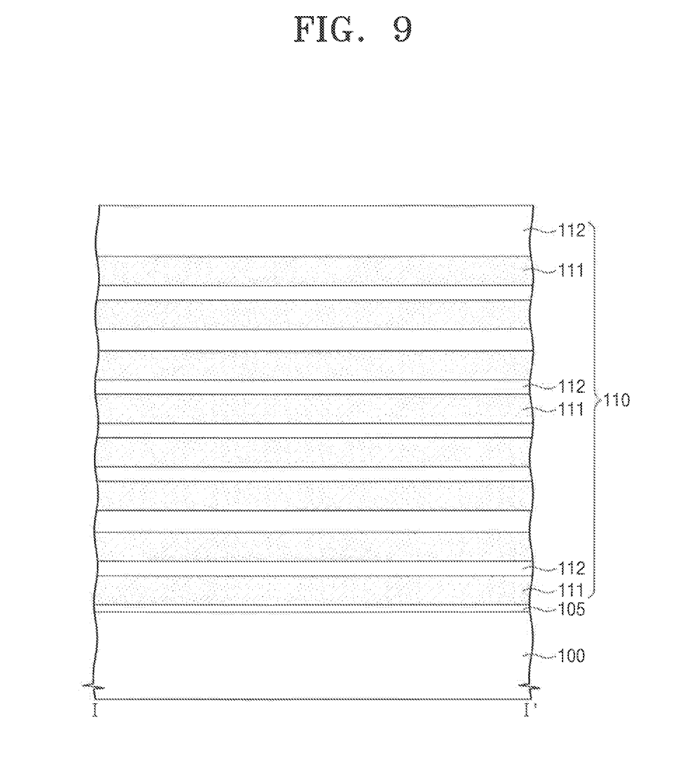

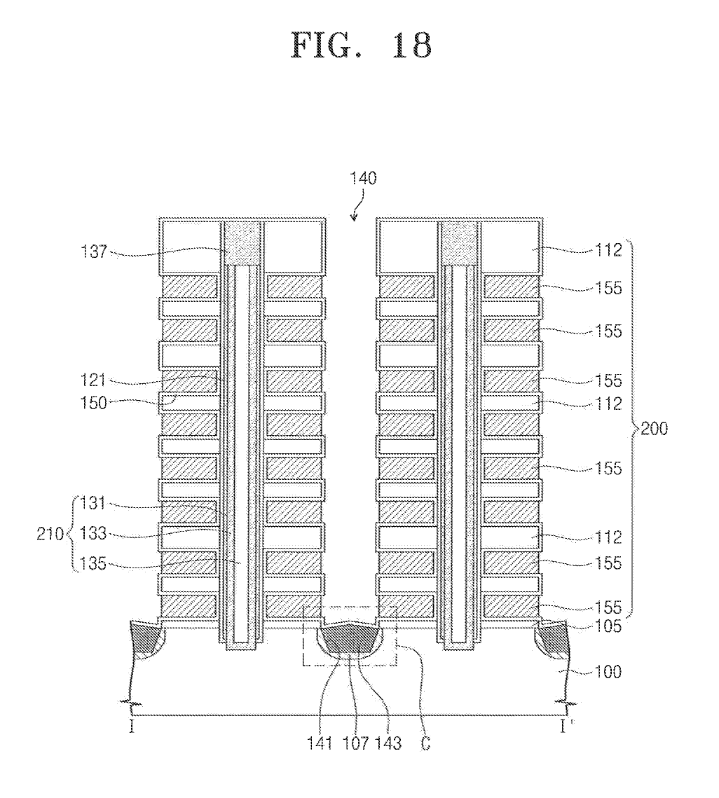

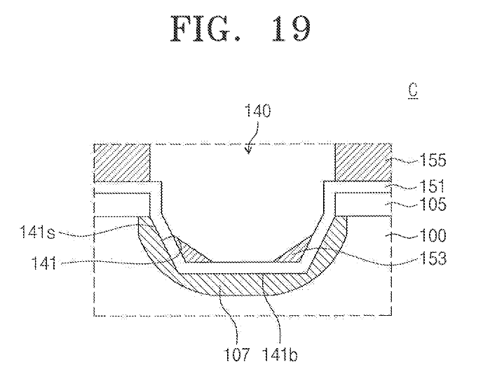

Hereinafter, a method of fabricating a 3D semiconductor memory device according to an exemplary embodiment will be described with reference to FIGS. 9 to 18. FIGS. 9 to 18 are cross-sectional views taken along line I-I′ of FIG. 2 to illustrate a method of fabricating a 3D semiconductor memory device according to an exemplary embodiment of the inventive concept. FIG. 19 is an enlarged view corresponding to a portion ‘C’ of FIG. 18 to illustrate a comparison example not including a third semiconductor pattern of FIG. 18.

Referring to FIG. 9, sacrificial layers 111 and insulating layers 112 are alternately and repeatedly stacked on a substrate 100 to form a thin layer structure 110.

The substrate 100 may include a semiconductor material. For example, the substrate 100 may he a silicon substrate, a germanium substrate, or a silicon-germanium substrate. Alternatively, the substrate 100 may include a device layer having a transistor and an insulating material covering the transistor. In this case, the thin layer structure 110 may be vertically stacked on the device layer.

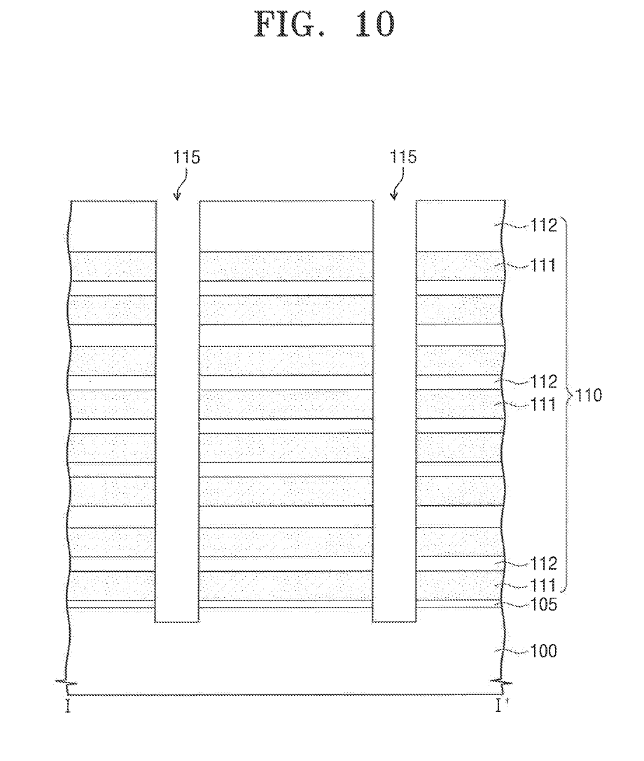

The sacrificial layers 111 may be formed of a material having etch selectivity with respect to the insulating layers 112. For example, the sacrificial layers 111 may be etched at a higher rate than the insulating layers 112 in a wet and/or dry etching process so that the sacrificial layers 111 may be selectively removed from the thin layer structure 110. A wet etching process may have better etch selectivity compared to a dry etching process. The etching process will be described in detail with reference to FIG. 10.

The thicknesses of the sacrificial layers 111 may be substantially equal to each other. Alternatively, the lowermost and uppermost sacrificial layers of the sacrificial layers 111 may be thicker than other sacrificial layers 111 disposed between the lowermost and uppermost sacrificial layers.

The thicknesses of the insulating layers 112 may be substantially equal to each other. Alternatively, at least one of the insulating layers 112 may be different from other insulating layers 112 in thickness.

The sacrificial layers 111 and the insulating layers 112 may be deposited using a thermal CVD technique, a plasma-enhanced CVD technique, a physical CVD technique, or an atomic layer deposition (ALD) technique.

The insulating layers 112 may be formed of an insulating material. The sacrificial layers 111 may be formed of an insulating material having etch selective with respect to the insulating layers 112. For example, each of the sacrificial layers 111 may include at least one of a silicon layer, a silicon oxide layer, a silicon carbide layer, a silicon oxynitride layer, and a silicon nitride layer. Each of the insulating layers 112 may include at least one of a silicon layer, a silicon oxide layer, a silicon carbide layer, a silicon oxynitride layer, and a silicon nitride layer. The insulating layers 112 may be formed of a different material from the sacrificial layers 111. For example, the sacrificial layers 111 may be formed of silicon nitride layers, and the insulating layers 112 may be formed of silicon oxide layers. Alternatively, the sacrificial layers 111 may be formed of a conductive material.

A lower insulating layer 105 is formed between the substrate 100 and the thin layer structure 110. For example, the lower insulating layer 105 may be a silicon oxide layer formed by a thermal oxidation process. Alternatively, the lower insulating layer 105 may be a silicon oxide layer formed using a deposition technique. The lower insulating layer 105 may be thinner than the sacrificial layers 111 and the insulating layers 112 formed thereon. For example, the thickness of the lower insulating layer 105 may be in a range of about 200 Å to about 300 Å.

Referring to FIG. 10, openings 115 are formed to penetrate the thin layer structure 110. The openings 115 expose the substrate 100.

The openings 115 be hole-shaped. Each of the openings 115 may have a hole-shape of which an aspect ratio may be five or more. The aspect ratio of an opening 115 is a ratio of its depth to its width. The openings 115, when viewed from the above, may be two-dimensionally arranged in the top surface of the substrate 100. For example, the openings 115 may be arranged in a straight line along one direction. Alternatively, the openings 115 may be arranged in a zigzag form along one direction.

A mask pattern (not shown) may be formed on the thin layer structure 110, and then the thin layer structure may be anisotropically etched using the mask pattern (not shown) as an etch mask to form the openings 115. The top surface of the substrate 100 may be over-etched in the anisotropic etching process such that the exposed top surface of the substrate through the openings 115 may be recessed in a predetermined depth. The lower width of the opening 115 may he smaller than the upper width of the opening 115.

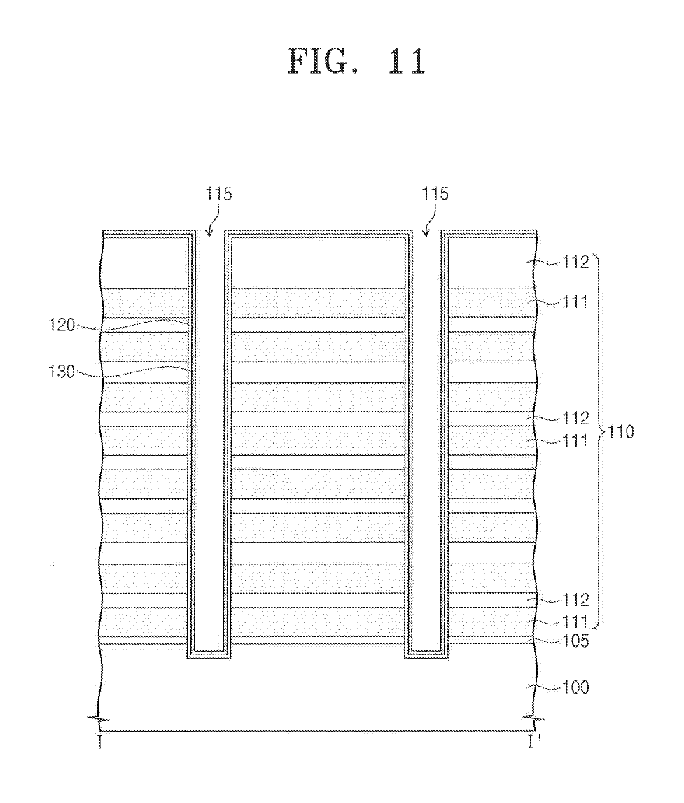

Referring to FIG. 11, a vertical insulating layer 120 and a first semiconductor layer 130 are sequentially formed in the openings 115 without filling up the openings 115. For example, the inner sidewalls of the opening 115 is first lined with the vertical insulating layer 120. The vertical insulating layer 120 is lined with the first semiconductor layer 130.

The vertical insulating layer 120 and the first semiconductor layer 130 may partially fill the openings 115. The total thickness of the vertical insulating layer 120 and the first semiconductor layer 130 may be smaller than a half of the width of the opening 115. For example, the vertical insulating layer 120 and the first semiconductor layer 130 need not completely fill the openings 115. The vertical insulating layer 120 may entirely cover the top surface of the substrate 100 exposed by the openings 115.

The vertical insulating layer 120 may be deposited using a plasma-enhanced CVD technique, a physical CVD technique, or an ALD technique.

The vertical insulating layer 120 may be formed of thin layers. For example, the vertical insulating layer 120 may include a charge storage layer used as a memory element of a charge trap-type flash memory device and a tunnel insulating layer. Alternatively, the vertical insulating layer 120 may include a first blocking insulating layer, a charge storage layer, and a tunnel insulating layer. The vertical insulating layer 120 may have various structures as illustrated in FIGS. 6 to 8. The vertical insulating layer 120 may be omitted.

The first semiconductor layer 130 is conformally formed on the vertical insulating layer 120. The first semiconductor layer 130 may include a semiconductor material (e.g., poly-crystalline silicon, single-crystalline silicon, or amorphous silicon) formed using a CVD technique or an ALD technique. Alternatively, the first semiconductor layer 130 may include one of an organic semiconductor layer or a carbon nano structure.

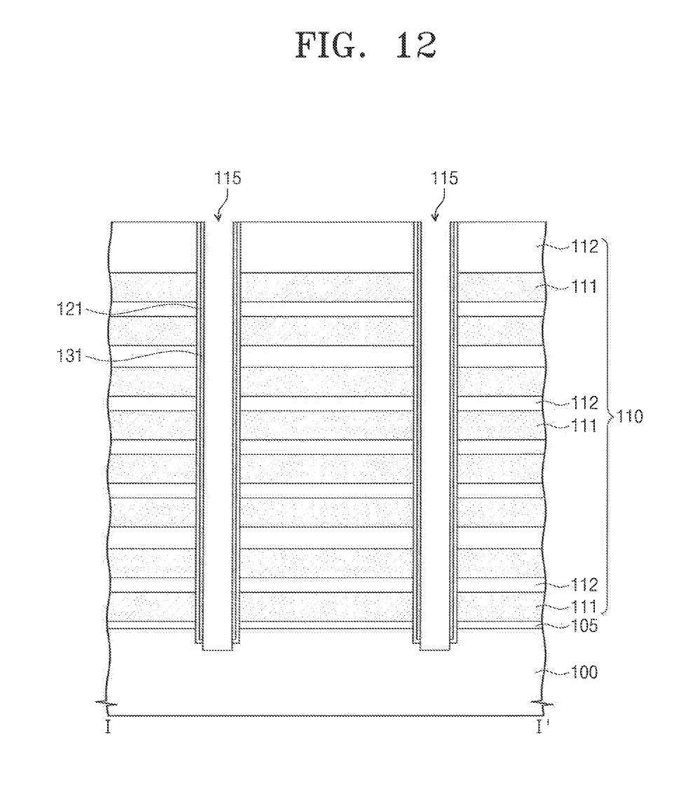

Referring to FIG. 12, a first semiconductor pattern 131 and a vertical insulating pattern 121 are formed only on the inner sidewall of the opening 115 using an anisotropic etching process. For example, the first semiconductor layer 130 and the vertical insulating layer 120 formed on bottom surfaces of the openings 115 may be etched to expose the top surface of the substrate 100 in the openings 115. Thus, the first semiconductor pattern 131 and the vertical insulating pattern 121 may be formed on the inner sidewall of the opening 115. Each of the vertical insulating pattern 121 and the first semiconductor pattern 131 may have a hollow cylindrical shape of which both ends are open. In addition, the exposed top surface of the substrate 100 may be over-etched in an anisotropic etching process such that the substrate 100 may be recessed in a predetermined depth.

A portion of the vertical insulating layer 120 of FIG. 11 disposed under the first semiconductor pattern 131 need not be etched during the anisotropic etching process. In this case, the vertical insulating pattern 121 may include a bottom portion disposed between a bottom surface of the first semiconductor pattern 131 and the top surface of the substrate 100.

A top surface of the thin layer structure 110 is exposed by the anisotropic etching process performed on the first semiconductor layer 130 and the vertical insulating layer 120 of FIG. 11. Thus, the vertical insulating pattern 121 and the first semiconductor pattern 131 are locally disposed in each of the openings 115. The vertical insulating patterns 121 and the first semiconductor patterns 131 in the openings 115 may be two-dimensionally arranged when viewed from the above.

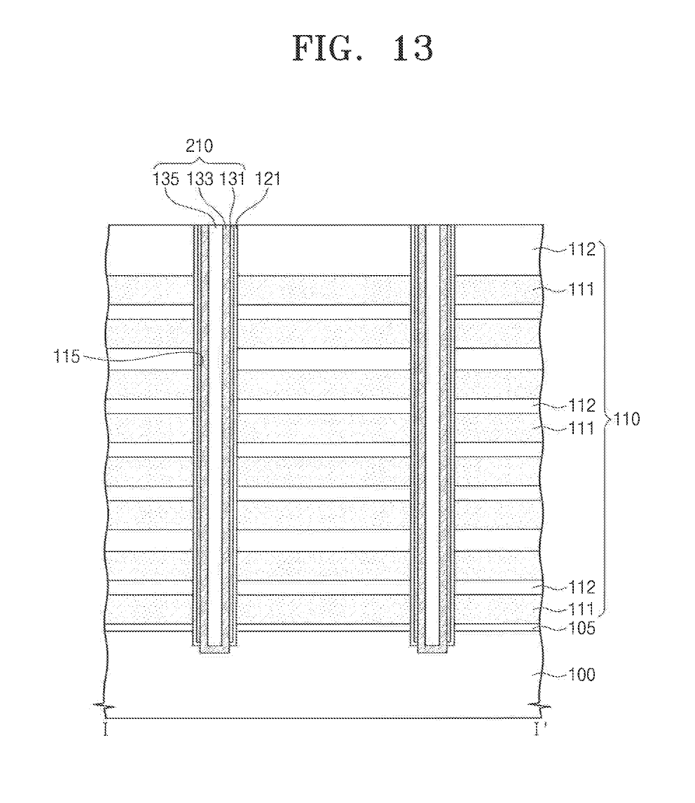

Referring to FIG. 13, a second semiconductor pattern 133 and a filling insulation pattern 135 are formed on the resultant structure of FIG. 12,

For example, a second semiconductor layer and a filling insulation layer may he sequentially formed in the opening 115 having the vertical insulating pattern 121 and the first semiconductor pattern 131. The second semiconductor layer and the filling insulation layer may be then planarized until the top surface of the thin layer structure 110 is exposed to form the second semiconductor pattern 133 and the filling insulation pattern 135,

The second semiconductor layer may include a semiconductor material (e.g., poly-crystalline silicon, single-crystalline silicon, or amorphous silicon) formed using a CVD technique or an ALD technique. The second semiconductor layer may be conformally formed in the opening 115 and may partially fill the opening 115. Thus, the second semiconductor pattern 133 may have a cup-shape in the opening 115. Alternatively, the second semiconductor pattern 133 may be formed to completely fill the opening 115.

The tilling insulation pattern 135 is formed to till the opening 115 having the second semiconductor pattern 133. The filling insulation pattern 135 may include at least one of silicon oxide and insulating materials formed using a spin-on-glass (SOG) technique. The first and second semiconductor patterns 131 and 133, and the filling insulation pattern 135 disposed in each of the openings 115 may constitute a channel structure 210.

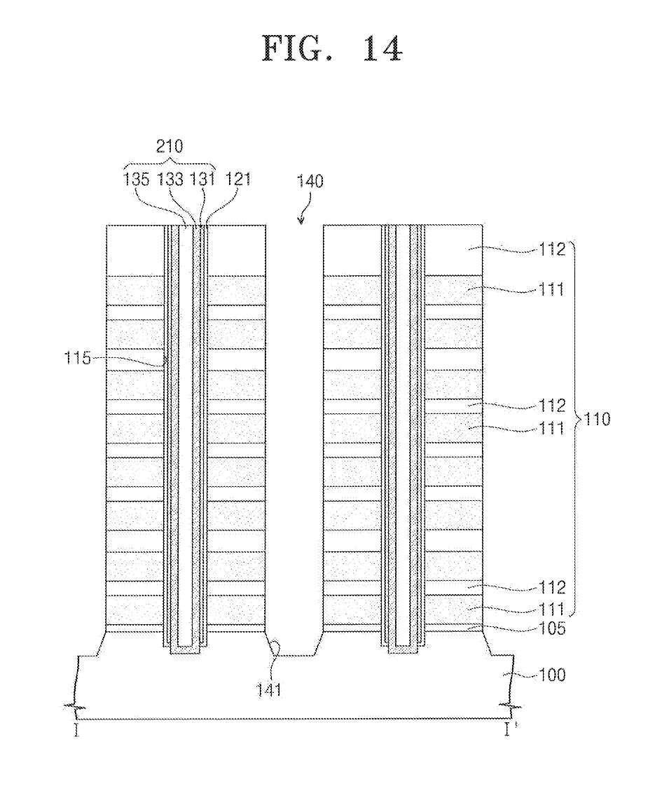

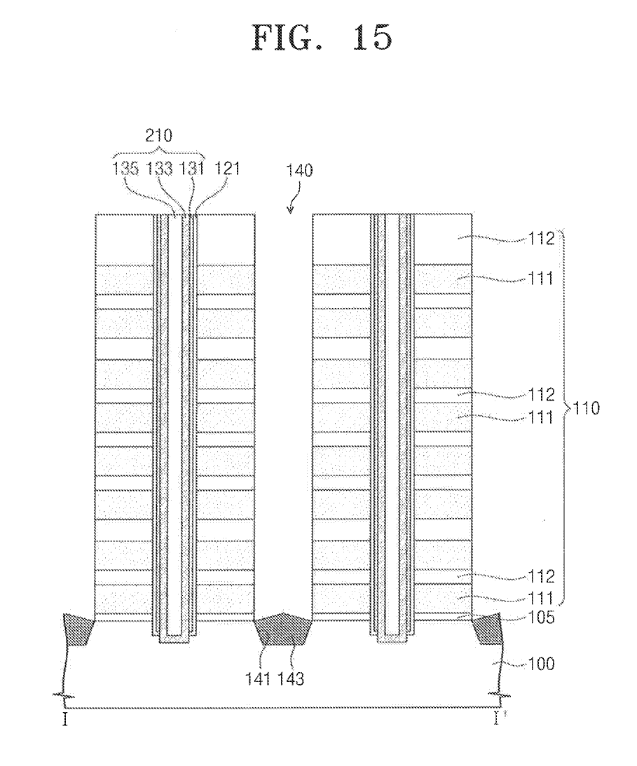

Referring to FIG. 14, trenches 140 are formed between the openings 115 in the thin layer structure 110. The trenches 140 expose the substrate 100 disposed between the openings 115.

For example, a mask pattern (not shown) may be formed on the thin layer structure 110. The mask pattern may define planar positions of the trenches 140 to be formed in a later process step. The thin layer structure 110 may he anisotropically etched using the mask pattern as an etch mask to form the trenches 140.

The trenches 140 are spaced apart from the first and second semiconductor patterns 131 and 133, exposing sidewalls of the patterned sacrificial layers 111 and sidewalls of the patterned insulating layers 112. Each of the trenches 140 may have a linear shape or a rectangular shape when viewed from the above. The trenches 140 expose a top surface of the substrate 100. At this time, the top surface, which is exposed by the trenches 140, of the substrate 100 may be over-etched to form a recess region 141 in the substrate 100 under each of the trenches 140. The recess region 141 may be defined by inclined surfaces 141s of FIG. 4 sloping downward from the top surface of the substrate 100 and a bottom surface 141b of FIG. 4 disposed between the inclined surfaces 141s. For example, a width of an upper region of the recess region 141 may be greater than a width of a lower region of the recess region 141.

Referring to FIG. 15, a third semiconductor pattern 143 is formed to fill the recess region 141.

For example, the third semiconductor pattern 143 may be formed by performing a selective epitaxial growth (SEG) process using the substrate 100 exposed by the recess region 141 as a seed layer. In this case, the third semiconductor pattern 143 may have a single-crystalline structure or a poly-crystalline structure having a grain size greater than that of a semiconductor material formed by a CVD technique. The third semiconductor pattern 143 may include a semiconductor material including silicon, germanium, or silicon-germanium. The semiconductor material may be in a single crystalline structure or a poly-crystalline structure. However, the inventive concept is not limited thereto, and the semiconductor pattern 143 may be formed of various materials. For example, the third semiconductor pattern 143 may include at least one of a carbon nano structure, an organic semiconductor material, and a compound semiconductor material.

Referring back to FIGS. 4 and 5, the third semiconductor pattern 143 may have various shape in its top surface. In FIG. 5, the third semiconductor pattern 143 partially fills the recess region 141, having a concave top surface lower than the top surface of the substrate 100. In FIG. 4, the third semiconductor pattern 143 completely fills the recess region 141, having a convex top surface higher than the top surface of the substrate 100. In an initial state of the SEG process, the third semiconductor pattern 143 is formed on the inclined surfaces 143s and the bottom surface 143b, forming a concave top shape. The third semiconductor pattern 143 may be formed laterally from the inclined surfaces due to the inclined surface 143s. As the SEG process progresses, the third semiconductor pattern 143 may start to protrude upward from the substrate 100, forming the convex top shape. The topmost end of the convex top surface of the third semiconductor pattern 143 may be lower than a bottom surface of the lowermost gate pattern 155. The height H1 between the top surface of the substrate 100 and the topmost end of the convex top surface in the third semiconductor pattern 143 may be varied according to the characteristics of the SEG process. For example, the height H1 may be about 200 Å or less.

If the top surface of the semiconductor pattern 143 has the concave shape, the bottommost end of the concave top surface in the third semiconductor pattern 143 is lower than the top surface of the substrate 100, as shown in FIG. 5. The height H2 between the bottommost portion of the top surface of the third semiconductor pattern 143 and the top surface of the substrate 100 may be varied according to the characteristics of the SEG process. For example, the height H2 may be about 100 Å or less.

The third semiconductor pattern 143 may have a conductivity type opposite to that of the substrate 100. The third semiconductor pattern 143 may be doped in-situ with dopants of the conductivity type opposite to that of the substrate 100 during the SEG process. The concentration of the dopants may be changed during the in-situ doping process such that the third semiconductor pattern 143 may be non-uniform in the doping concentration thereof. Alternatively, dopant ions may be implanted into the third semiconductor pattern 143 after the formation of the third semiconductor pattern 143.

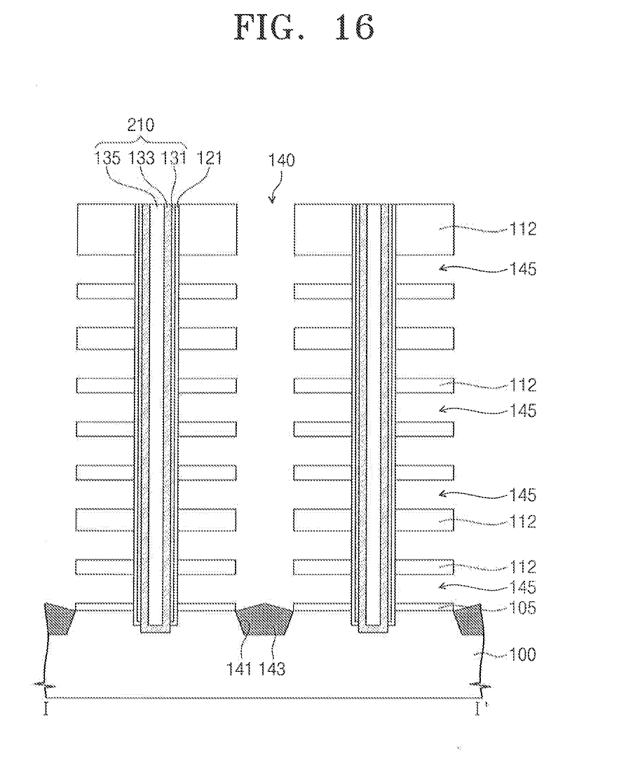

Referring to FIG. 16, the sacrificial layers 111 exposed by the trenches 140 are removed to form gate regions 145 between the insulating layers 112.

The gate regions 145 are formed by removing the sacrificial layers 111 disposed between the insulating layers 112. The gate regions 145 horizontally extend from the trench 140 toward the gate regions 145, exposing portions of the sidewall of the vertical insulating pattern 121. For example, each of the gate regions 145 are defined by adjacent insulating layers 112 and the sidewall of the vertical insulating pattern 121.

For example, if the vertical insulating pattern 121 includes a tunnel insulating layer, the gate regions 145 may expose portions of the tunnel insulating layer. If the vertical insulating pattern 121 includes a charge storage layer and a tunnel insulating layer, the gate regions 145 may expose portions of the charge storage layer if the vertical insulating pattern 121 includes a blocking insulating layer, a charge storage layer, and a tunnel insulating layer, the gate regions 145 may expose the blocking insulating layer.

The gate regions 145 may be formed by isotropically etching the sacrificial layers 111 using an etch recipe having etch selectivity of the sacrificial layers 111 with respect to the insulating layers 112 and the third semiconductor pattern 143. At this time, the sacrificial layers iii may be completely removed by the isotropic etching process. For example, if the sacrificial layers 111 are silicon nitride layers and the insulating layers 112 are silicon oxide layers, the isotropic etching process may he performed using an etching solution including phosphoric acid.

Due to the etch selectivity with respect to the sacrificial layers 111 and the insulating layers 112, the third semiconductor pattern 143 remains during the formation of the gate regions 145.

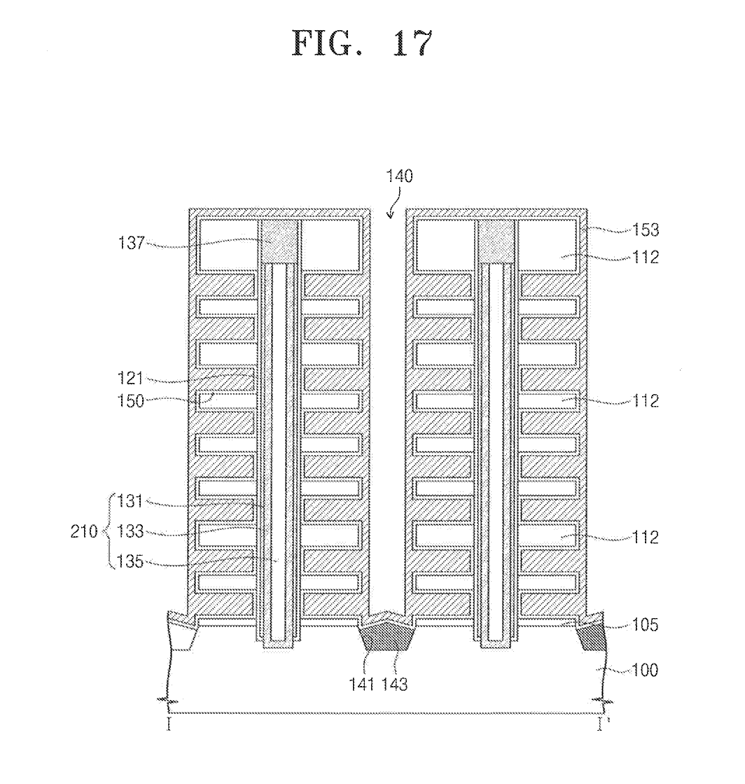

Referring to FIG. 17, a horizontal insulating layer 150 may be formed on the resulting structure of FIG. 16 having the gate regions 145. The horizontal insulating layer 150 conformally covers inner surfaces of the gate regions 145 in a sinuous manner.

The horizontal insulating layer 150 may be formed of at least one thin layer. For example, the horizontal insulating layer 150 may include a blocking insulating layer of the charge trap-type flash memory transistor.

A gate conductive layer 153 is formed to completely fill the gate regions 145 having the horizontal insulating layer 150 and to conformally cover inner sidewalls of the trenches 140. The gate conductive layer 153 also conformally covers the horizontal insulating layer 150 formed on the uppermost insulating layer 112 and the third semiconductor patterns 143. Alternatively, the gate conductive layer 153 may fill the gate regions 145 and the trenches 140. The gate conductive layer 153 may include at least one of doped silicon, metal materials, metal nitrides, and metal suicides. In an exemplary embodiment, the gate conductive layer 153 may include at least one of tantalum nitride and tungsten.

The vertical insulating pattern 121 may be omitted. In this case, each of the gate regions 145 may be defined by two insulating layers 112 vertically adjacent to each other and a sidewall of the channel structure 210. The horizontal insulating layer 150 may he conformally formed on the substrate 100 to cover inner surfaces of the gate regions 145. In this case, the horizontal insulating layer 150 may include a tunnel insulating layer, a charge storage layer, and a blocking insulating layer.

Before the formation of the horizontal insulating layer 150, a conductive pad 137 may be formed to be connected to the first and second semiconductor patterns 131 and 133 of each of the channel structures 210. Upper portions of the first and second semiconductor patterns 131 and 133 may be recessed, and the recessed region may be then filled with a conductive material to form the conductive pad 137. Alternatively, the conductive pad 137 may be doped with dopants of a conductivity type different from the conductivity type of the first and second semiconductor patterns 131 and 133 such that the conductive pad 137 and the first and second semiconductor patterns 131 and 133 may constitute a diode.

Referring to FIG. 18, gate patterns 155 may be formed.

For example, the gate conductive layer 153 of FIG. 17 in the trenches 140 may be removed by an isotropic etching process to form the gate patterns 155. Thus, the gate patterns 155 may be locally formed in the gate regions 145. If the third semiconductor pattern 143 according to an exemplary embodiment of the inventive concept does not exist, a portion of the gate conductive layer 153 may remain in a corner region disposed between the inclined surface 141s and the bottom surface 141b of the recess region 141 after the etching process of forming the gate patterns 155, as shown in FIG. 19. Thus, an additional etching process or over-etching process may be required to completely remove the remaining portion of the gate conductive layer 153 of FIG. 19. In this case, the gate patterns 155 may be laterally recessed by the additional etching process such that widths of the gate patterns 155 may be reduced. Such reduction in the width of the gate pattern 155 may increase the resistance of the gate patterns 155.

According to an exemplary embodiment of the inventive concept, the third semiconductor pattern 143 may be formed to fill the recess region 141 in place of the gate conductive layer 153 such that the gate conductive layer 153 need not fill the recess region 141. Accordingly, the additional etching process for removing the remaining portion 153 of FIG. 19 may be avoided, and thus the over-etching of the gate patterns 155 to remove the remaining portion 153 may be prevented. Accordingly, the formation of the third semiconductor layer 143 in the recess region 141 may prevent the increase of the resistance in the gate patterns 155.

If the gate conductive layer 153 of FIG. 17 is formed to completely fill the trenches 140, the gate patterns 155 may be formed by anisotropically etching the gate conductive layer 153 disposed in the trenches 140.

Dopant regions may be formed under the third semiconductor patterns 143 in the substrate 100 to form common source regions 107 after the formation of the gate patterns 155. The common source region 107 includes the third semiconductor pattern 143 and the dopant region thereunder. The dopant regions may surround the third semiconductor patterns 143, respectively. The common source regions 107 may be formed using an ion implantation process. For example, the third semiconductor patterns 143 exposed by the trenches 143 and the dopant regions of the substrate 100 adjacent to the third semiconductor patterns 143 may be subject to an ion implantation process, and thus the third semiconductor patterns 143 and the dopant regions may be doped in the ion implantation process. The inventive concept is not limited thereto, and the common source regions 107 may be formed using various processes. For example, the third semiconductor pattern 143 may be doped in-situ with dopants during the formation of the third semiconductor pattern 143 and then, the dopants of the third semiconductor patterns 143 may be diffused into the substrate 100 to form the dopant regions under the third semiconductor patterns 143. In this case, an ion implantation process may be omitted.

The common source regions 107 may have a conductivity type different from that of the first and second semiconductor patterns 131 and 133. In addition, the common source regions 107 and the substrate 100 may constitute a PN-junction.

Referring back to FIGS. 2 and 3, a device isolation pattern 160 and a horizontal insulating pattern 151 may be formed.

A device isolation insulating layer may be formed to completely fill the trenches 140, and the device isolation insulating layer and the horizontal insulating layer 150 of FIG. 18 may be then planarized until the uppermost insulating layer 112 is exposed to form the device isolation pattern 160 and the horizontal insulating pattern 151. The device isolation pattern 160 may be formed of at least one of a silicon oxide layer, a silicon nitride layer, and a silicon oxynitride layer.

Next, an interlayer insulating layer 165, contact plugs 171, and a bit line 175 may be formed. The contact plugs 171 may be connected to the conductive pads 137, respectively. The bit line 175 may be electrically connected to the first and second semiconductor patterns 131 and 133 through the contact plugs 171 and may cross over the gate patterns 155. The interlayer insulating layer 165 may be formed of the same material as the device isolation pattern 160, and the contact plugs 171 may be formed of at least one of doped silicon and metallic materials.

According to an exemplary embodiment of the inventive concept, a semiconductor pattern may be formed to fill the recess region in the substrate under the device isolation pattern, and thus the gate conductive layer disposed on the semiconductor pattern may be removed without over-etching the gate conductive layer disposed between the insulating layers 112 in an etching process for locally forming the gate patterns in the gate regions. As a result, the laterally etched amount of the gate patterns may be reduced during the etching process, as compared with the case that the semiconductor pattern does not exist. For example, the reduction in the widths of the gate patterns may be minimized such that the increase of the resistance values of the gate patterns may be minimized or prevented. Thus, the performance of the 3D semiconductor memory device may be increased.

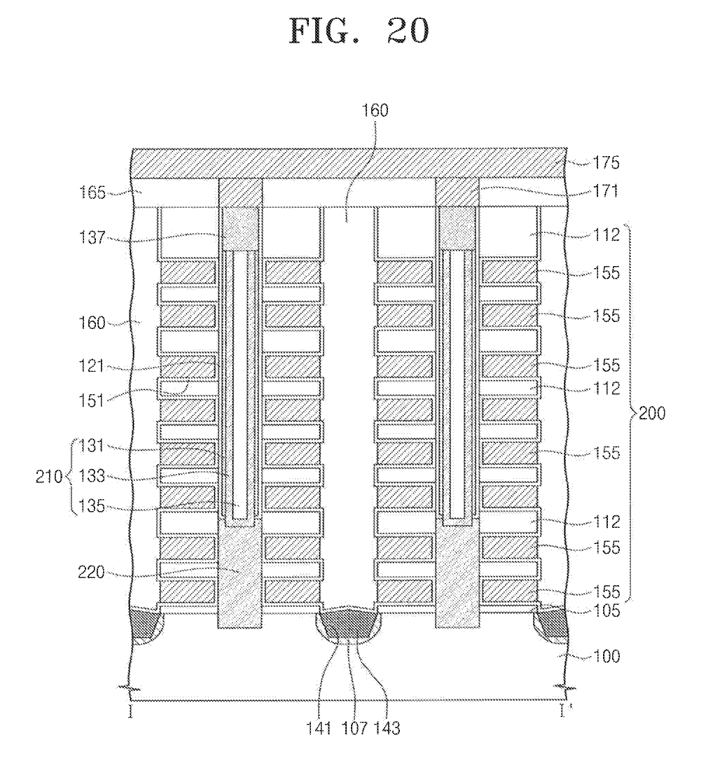

FIG. 20 is a cross-sectional view taken along line I-I′ of FIG. 2, to illustrate a 3D semiconductor memory device according to an exemplary embodiment of the inventive concept. The descriptions of the elements described above will be omitted or mentioned briefly hereinafter for the convenience of description,

Referring to FIG. 20, a 3D semiconductor memory device includes a lower semiconductor pattern 220 which penetrates a lower portion of the stack structure 200 and is connected to the substrate 100. A bottom surface of the lower semiconductor pattern 220 is lower than the top surface of the substrate 100. For example, a bottom portion of the lower semiconductor pattern 220 is inserted into the substrate 100.

The insulating layer 112 adjacent to the lower semiconductor pattern 220 is in direct contact with a sidewall of the lower semiconductor pattern 220. The horizontal insulating pattern 151 is disposed between the lower semiconductor pattern 220 and the gate patterns 155 adjacent to the lower semiconductor pattern 220.

A vertical insulating pattern 121 and a channel structure 210 are disposed on the lower semiconductor pattern 220. The channel structure 210 penetrates an upper portion of the stack structure 200 and is in contact with the lower semiconductor pattern 220. As described above, the channel structure 210 includes the first and second semiconductor patterns 131 and 133 and the filling insulation pattern 135. The second semiconductor pattern 133 may electrically connect the first semiconductor pattern 131 to the lower semiconductor pattern 220.

The lower semiconductor pattern 220 may serve as a channel region of the ground selection transistor GST as described with reference to FIG. 1. The lower semiconductor pattern 220 may be formed of a semiconductor material having the same conductivity type as the substrate 100. The lower semiconductor pattern 220 may be an epitaxial pattern formed using one of laser crystallization techniques and an epitaxial technique which uses the substrate 100 formed of a semiconductor material as a seed. In this case, the lower semiconductor pattern 220 may have a single-crystalline structure, or a poly-crystalline structure having a grain size greater than that of a semiconductor material formed by a CVD technique. For example, the lower semiconductor pattern 220 may be formed of a poly-crystalline semiconductor material (e.g., poly-crystalline silicon).

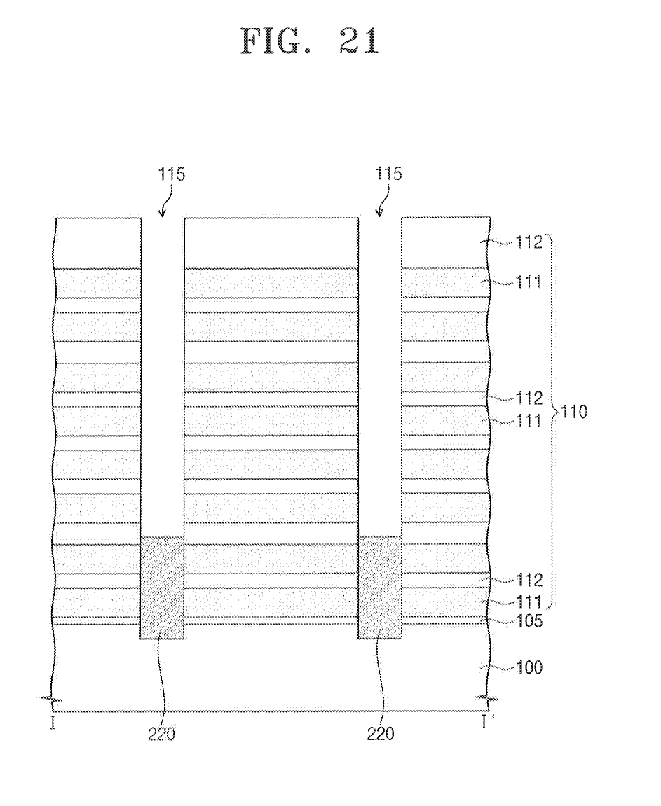

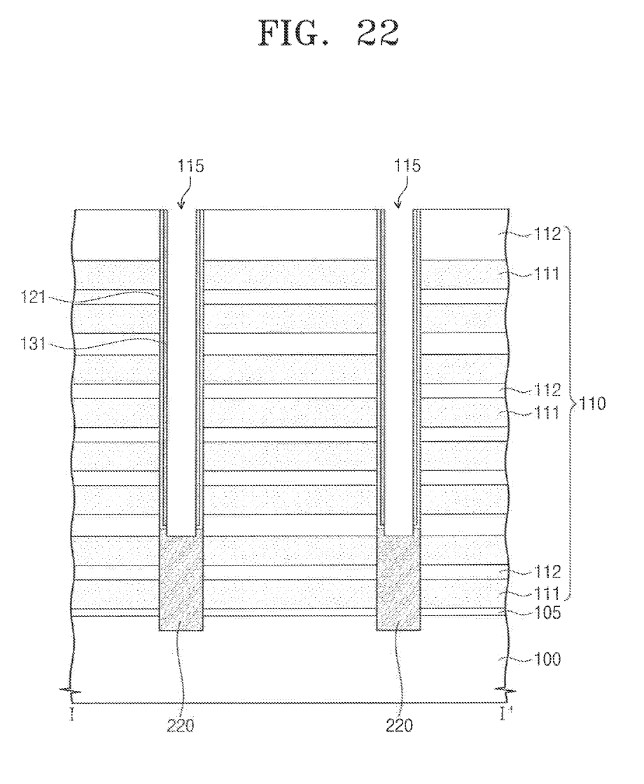

FIGS. 21 to 23 are cross-sectional views taken along line I-I′ of FIG. 2 to illustrate a method of fabricating the 3D semiconductor memory device of FIG. 20 according to an exemplary embodiment of the inventive concept. The descriptions of the elements described above will he omitted or mentioned briefly hereinafter for the convenience of description.

Referring to FIG. 21, lower semiconductor patterns 220 are formed to fill lower regions of the openings 115 in the resultant structure of FIG. 10.

The lower semiconductor patterns 220 are in direct contact with sidewalls of the sacrificial layers 111 and the insulating layers 112, which constitute an inner sidewall of lower regions of the openings 115. The lower semiconductor patterns 220 cover the sidewall of at least one sacrificial layer 111. Top surfaces of the lower semiconductor patterns 220 are disposed at a level between sacrificial layers 111 vertically adjacent to each other.

For example, the lower semiconductor patterns 220 may be formed by performing, a selective epitaxial growth (SEG) process using the substrate 100 exposed by the openings 115 as a seed layer. The lower semiconductor patterns 220 may have a pillar-shape filling the lower regions of the openings 115. In this case, the lower semiconductor patterns 220 may have a single-crystalline structure, or a poly-crystalline structure having a grain size greater than that of a semiconductor material formed by a CVD technique. The lower semiconductor patterns 220 may include silicon. The semiconductor patterns 220 may be a single crystalline structure or a poly-crystalline structure. For example, the lower semiconductor patterns 220 may be formed of a poly-crystalline semiconductor material (e,g., poly-crystalline silicon). However, the inventive concept is not limited thereto, and the lower semiconductor patterns 220 may be formed of various materials. For example, the lower semiconductor patterns 220 may include at least one of a carbon nano structure, an organic semiconductor material, and a compound semiconductor material.

The lower semiconductor patterns 220 may have the same conductivity type as the substrate 100. The lower semiconductor patterns 220 may be doped in-situ with dopants during the SEG process. Alternatively, dopant ions may be implanted into the lower semiconductor patterns 220 after the formation of the lower semiconductor patterns 220.

Referring to FIG. 22, a vertical insulating pattern 121 and a first semiconductor pattern 131 are formed to cover an inner sidewall of the opening 115 having the lower semiconductor pattern 220. The top surfaces of the lower semiconductor patterns 220 disposed between the first semiconductor pattern 131 are exposed through the openings 115. Materials and formation processes of the vertical insulation pattern 121 and the first semiconductor pattern 131 of FIG. 22 may he substantially the same as those of the vertical insulation pattern 121 and the first semiconductor pattern 131 of FIG. 12 except for the feature that the patterns 121 and 131 of FIG. 22 expose the top surface of the lower semiconductor pattern 220.

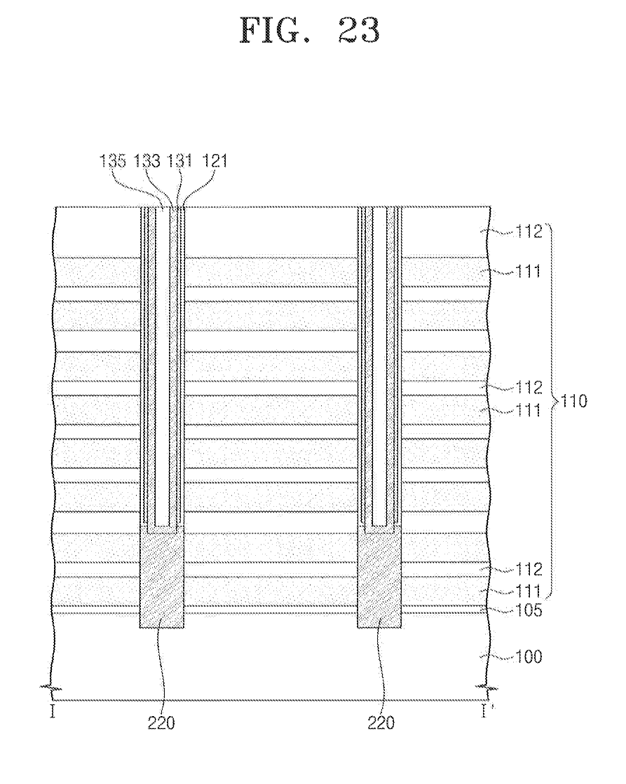

Referring to FIG. 23, a second semiconductor pattern 133 and a filling insulation pattern 135 may be formed on the substrate 100 having the vertical insulating pattern 121 and the first semiconductor pattern 131. Materials and formation processes of the second semiconductor pattern 133 and the filling insulation pattern 135 of FIG. 23 may he substantially the same as those of the second semiconductor pattern 133 and the filling insulation pattern 135 of FIG. 13 except for the feature that the second semiconductor pattern 133 of FIG. 23 is connected to the lower semiconductor pattern 220.

Next, the processes described with reference to FIGS. 14 to 18 may he performed on the resultant structure of FIG. 23 to fabricate the 3D semiconductor memory device of FIG. 20.

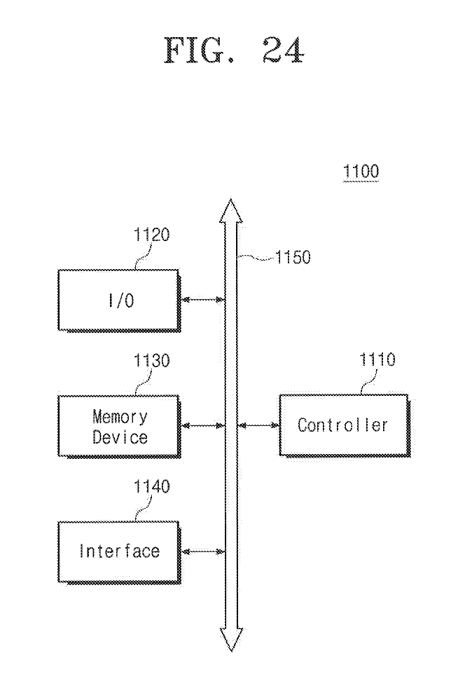

FIG. 24 is a schematic block diagram illustrating a memory system including a 3D semiconductor memory device according to an exemplary embodiment of the inventive concept.

Referring to FIG. 24, a memory system 1100 may be applied to a personal digital assistant (PDA), a portable computer, a web tablet, a wireless phone, a mobile phone, a digital music player, a memory card, or other electronic products receiving and/or transmitting information data by wireless.

The memory system 1100 includes a controller 1110, an input/output (I/O) unit 1120 (e.g., a keypad, a keyboard, and/or a display), a memory device 1130, an interface unit 1140 and a data bus 1150. The memory device 1130 and the interface unit 1140 may communicate with each other through the data bus 1150.

The controller 1110 may include at least one of a microprocessor, a digital signal processor, a microcontroller, and other logic device intended to perform a similar function thereof. The memory device 1130 may store data processed by the controller 1110. The I/O unit 1120 may receive data or signals from the outside of the memory system 1100 or may output data or signals to the outside of the memory system 1100.

The memory device 1130 may include a 3D semiconductor memory device according to an exemplary embodiment of the inventive concept. The memory device 1130 may further include at least one of a random access volatile memory device and other various kinds of memory devices in addition to the 3D semiconductor memory device.

The interface unit 1140 may transmit electrical data to a communication network or may receive electrical data from a communication network.

The 3D semiconductor memory devices or the memory systems according to the inventive concept may be encapsulated using various packaging techniques. For example, 3D semiconductor memory devices or the memory systems according to the inventive concept may he encapsulated using any one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic metric quad flat package (PMQFP) technique, a plastic quad flat package (PQFP) technique, a small outline package (SOP) technique, a shrink small outline package (SSOP) technique, a thin small outline package (mop) technique, a thin quad flat package (TQFP) technique, a system in package (SIP) technique, a multi-chip package (MCP) technique, a wafer-level fabricated package (WFP) technique and a wafer-level processed stack package (WSP) technique.

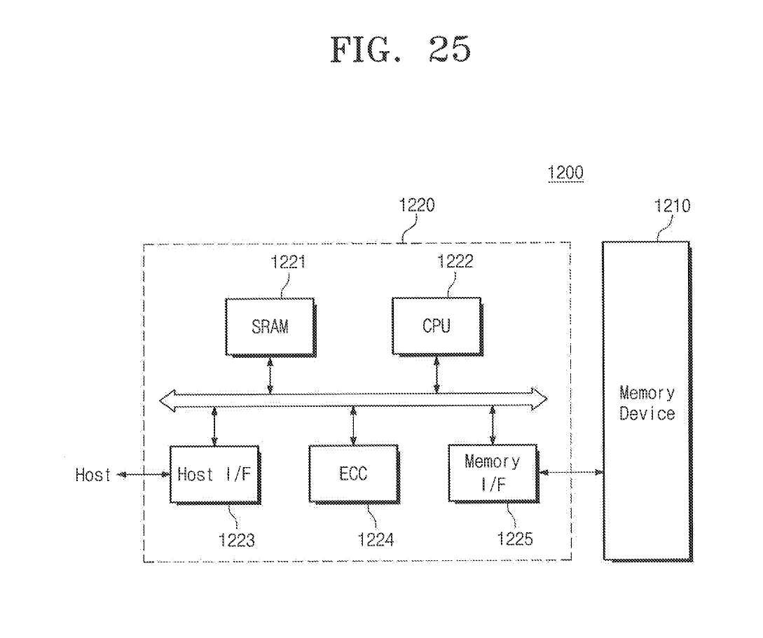

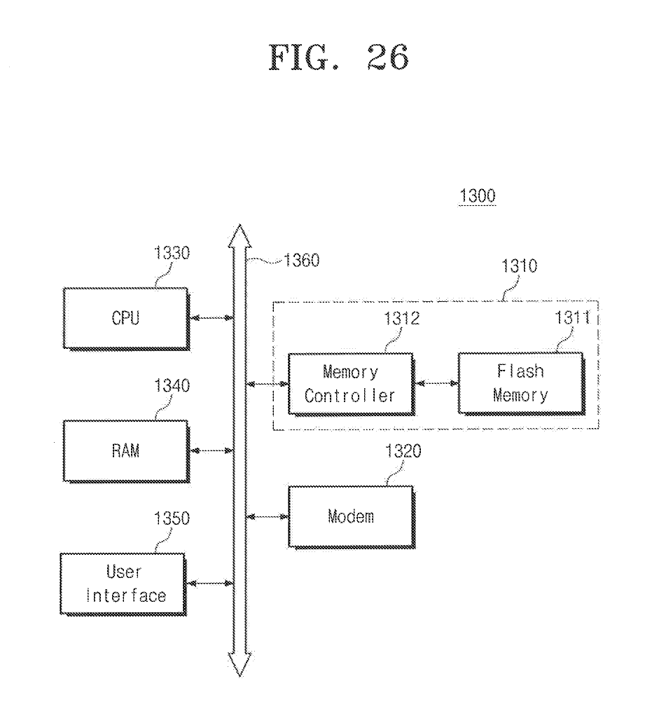

FIG. 25 is a schematic block diagram illustrating a memory card including a 3D semiconductor memory device according to an exemplary embodiment of the inventive concept.

Referring to FIG. 25, a memory card 1200 includes a flash memory device 1210 to store massive data. The flash memory device 1210 may include a 3D semiconductor memory device according to an exemplary embodiment of the inventive concept. The memory card 1200 may include a memory controller 1220 that controls data communication between a host and the flash memory device 1210.

A static random access memory (SRAM) device 1221 may be used as an operation memory of a central processing unit (CPU) 1222. A host interface unit 1223 may operate based on a data communication protocol between the memory system 1200 and the host. An error check and correction (FCC) block 1224 may detect and correct errors of data which are read out from the flash memory device 1210. A memory interface unit 1225 may interface with the flash memory device 1210 according to an exemplary embodiment of the inventive concept. The CPU 1222 may perform overall operations for data exchange of the memory controller 1220. The memory card 1200 may further include a read only memory (ROM) device that stores code data to interface with the host.

FIG. 26 is a schematic block diagram illustrating an information processing system including a 3D semiconductor memory device according to an exemplary embodiment of the inventive concept.

Referring to FIG. 26, a flash memory system 1310 is included in an information processing system 1300 such as a mobile device or a desk top computer. The flash memory system 1310 includes a 3D semiconductor memory device according to an exemplary embodiment of the inventive concept. The flash memory system 1310 includes a memory controller 1312 and a flash memory device 1311. The information processing system 1300 may include a modem 1320, a central processing unit (CPU) 1330, a random access memory (RAM) 1340 and a user interface unit 1350 which are electrically connected to the flash memory system 1310 through a system bus 1360. The flash memory system 1310 may be substantially the same as the aforementioned memory system or flash memory system. Data processed by the CPU 1330 or data inputted from the outside may be stored in the flash memory system 1310. Here, the flash memory system 1310 may be realized as a solid state disk (SSD) device. In this case, the information processing system 1300 may store massive data in the flash memory system 1310. Additionally, as reliability of the flash memory system 1310 may increase, the flash memory system 1310 may reduce a resource necessary to correct errors. An application chipset, a camera image processor (CIS), and an input/output unit may further be provided in the information processing system 1300.

While the present inventive concept has been shown and described with reference to exemplary embodiments thereof, it will be apparent to those of ordinary skill in the art that various changes in form and detail may be made therein without departing from the spirit and scope of the inventive concept as defined by the following claims.

What is claimed is:

1. A method of fabricating a three-dimensional (3D) semiconductor memory device, the method comprising:
alternately and repeatedly stacking sacrificial layers and insulating layers on a top surface of a substrate to form a thin layer structure;
forming a channel structure penetrating the thin layer structure to be in contact with the substrate;
forming a trench penetrating the thin layer structure, wherein the sacrificial layers, the insulating layers and the substrate are exposed in the trench;
forming a recess region in the substrate exposed by the trench;
forming a semiconductor pattern filling the recess region; and
replacing the sacrificial layers exposed by the trench with gate patterns.

2. The method of claim 1, wherein the semiconductor pattern has a convex top surface higher than the top surface of the substrate and completely fills the recess region.

3. The method of claim 1, wherein the semiconductor pattern has a concave top surface lower than the top surface of the substrate and partially fills the recess region.

4. The method of claim 1, wherein the forming of the semiconductor pattern is performed using a selective epitaxial growth (SEG) process in which dopants are in-situ doped in the semiconductor pattern.

5. The method of claim 1, further comprising:
implanting dopant ions into the semiconductor pattern after forming the semiconductor pattern.

6. The method of claim 1, wherein the replacing of the sacrificial layers with the gate patterns comprises:
removing the sacrificial layers exposed by the trench to form gate regions between the insulating layers; and
forming the gate patterns in the gate regions,
wherein the gate patterns are formed after the formation of the semiconductor pattern.

7. The method of claim 1, wherein the forming of the channel structure comprises:
forming a lower semiconductor pattern connected to the substrate, and
wherein the lower semiconductor pattern is formed by a selective epitaxial growth process.

8. A three-dimensional (3D) semiconductor memory device comprising:
a stack structure including gate patterns and insulating patterns alternately stacked on a top surface of a substrate, wherein the substrate includes a recess region of which a bottom surface is lower than the top surface of the substrate;
a channel structure disposed on a first sidewall of the stack structure and connected to the substrate;
a semiconductor pattern disposed in the recess region; and
a device isolation pattern disposed on a top surface of the semiconductor pattern and a second sidewall of the stack structure, wherein the first sidewall is opposite to the second sidewall.

9. The 3D semiconductor memory device of claim 8, wherein the top surface of the semiconductor pattern is curved.

10. The 3D semiconductor memory device of claim 9, wherein the curved top surface is convex, and
wherein the top surface of the semiconductor pattern is lower than a bottom surface of a lowermost gate pattern in the gate patterns.

11. The 3D semiconductor memory device of claim 10, wherein a height from the top surface of the substrate to a topmost end of the top surface of the semiconductor pattern is about 200 Å or less.

12. The 3D semiconductor memory device of claim 9, wherein the curved top surface is concave, and
wherein a height from a bottommost portion of the top surface of the semiconductor pattern to the top surface of the substrate is about 100 Å or less.

13. The 3D semiconductor memory device of claim 8, wherein the semiconductor pattern includes an epitaxial layer.

14. The 3D semiconductor memory device of claim 8, further comprising:
a data storage layer disposed between the channel structure and the gate patterns.

15. The 3D semiconductor memory device of claim 8, further comprising a lower semiconductor pattern disposed between the substrate and the channel structure, wherein the lower semiconductor pattern is connected to the substrate, and wherein the lower semiconductor pattern includes an epitaxial layer.

16. A three-dimensional (3D) semiconductor memory device comprising:
a substrate including a recess region including a sloped sidewall and a bottom surface, wherein the bottom surface of the recess region is lower than a top surface of the substrate;
a semiconductor pattern disposed in the recess region; and
first and second stack structures disposed on the top surface of the substrate and spaced apart from each other,
wherein the recess region is provided in the substrate between the first and second stack structures, and
wherein the first and second stack structures include gate patterns and insulating patterns alternately stacked.

17. The 3D semiconductor memory device of claim 16, wherein the substrate includes impurities of a first conductivity type, and the semiconductor pattern is doped with impurities of a second conductivity type.

18. The 3D semiconductor memory device of claim 16, further comprising a doping region disposed underneath the sloped sidewall and the bottom surface of the recess region in the substrate, wherein the substrate includes impurities of a first type conductivity, and the doping region is doped with a second conductivity type.

19. The 3D semiconductor memory device of claim 16, wherein a top surface of the semiconductor pattern is curved.

20. The 3D semiconductor memory device of claim 16, further comprising a horizontal insulating pattern disposed between the gate patterns and the insulating patterns.
